(19) United States
(12) Patent Application Publication
(10) Pub. No.: US 2022/0189359 A1
(43) Pub. Date: Jun. 16, 2022

(54) SHIFT REGISTER UNIT, GATE DRIVING CIRCUIT, AND DISPLAY PANEL

(71) Applicant: WUHAN CHINA STAR OPTOELECTRONICS SEMICONDUCTOR DISPLAY TECHNOLOGY CO., LTD., Wuhan (CN)

(72) Inventor: Zhenfei Cai, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/972,497

(22) PCT Filed: May 22, 2020
(86) PCT No.: PCT/CN2020/091788

§ 371 Date: Dec. 4, 2020

(30) Foreign Application Priority Data
Mar. 12, 2020 (CN) 202010168728.0

(51) Int. Cl. G09G 3/20; G11C 19/28

(52) U.S. Cl. CPC G09G 3/20; G11C 19/28; G09G 2320/0214; G09G 2310/0286; G09G 2310/0267; G09G 2310/08

(57) ABSTRACT

The present invention provides a shift register unit, a gate driving circuit, and a display panel. The shift register unit includes: a pull-up control module connected to an output end of an (n−1)th-stage scanning signal, a first node, and a third node; a pull-up module connected to a first clock signal, the first node, and an output end of a present-stage scanning signal; a leakage-proof module connected to the first clock signal and the third node.

### FIELD OF INVENTION

The present invention is related to the field of display technology, and specifically, to a shift register unit, a gate driving circuit, and a display panel.

### BACKGROUND OF INVENTION

A gate driving circuit is usually provided on an edge of a display panel. The gate driving circuit includes a plurality of cascaded shift register units. In a display stage, each stage of the shift register units controls a scanning line corresponding to pixels in a row to receive a high level, so that the pixels can display. After a previous-stage shift register unit receives a signal and completes a shift, an output signal is transmitted to a next-stage shift register unit in the cascade, thereby implementing a function of progressive scanning.

However, during a shift process of a current shift register unit, severe leakage occurs to Q points of transistors in a pull-up module and a pull-down module because of a large voltage difference between a source and a drain, thereby destabilizing the shift register unit.

Therefore, it is necessary to provide a shift register unit, a gate driving circuit, and a display panel to solve problems in the prior art.

### SUMMARY OF INVENTION

A purpose of the present invention is to provide a shift register unit, a gate driving circuit, and a display panel, which can prevent Q points from a leakage and improve stability of the shift register unit.

In order to solve the above problems, the present invention provides the shift register unit including:

a pull-up control module connected to an output end of an (n−1)th-stage scanning signal, a first node, and a third node, wherein n is greater than or equal to 2;

a pull-up module connected to a first clock signal, the first node, and an output end of a present-stage scanning signal;

a leakage-proof module connected to the first clock signal and the third node;

a pull-down control module connected to an output end of an (n+2)th-stage scanning signal and a second node;

a first pull-down module connected to the output end of the (n+2)th-stage scanning signal, the first node, the second node, and the third node;

a pull-down holding module connected to the output end of the (n−1)th-stage scanning signal, a first low direct current voltage, the second node, and the first pull-down module;

a second pull-down module connected to the second node, the output end of the present-stage scanning signal, and the first low direct current voltage; and

a bootstrap capacitor, wherein one end of the bootstrap capacitor is connected to the first node, and another end of the bootstrap capacitor is connected to the output end of the present-stage scanning signal.

The present invention further provides the gate driving circuit including a plurality of cascaded shift register units.

The present invention further provides the display panel including the above gate driving circuit.

The shift register unit, the gate drive circuit, and the display panel of the present invention can prevent a voltage difference between the sources and the drains of the transistors in the pull-up control module and the pull-down module from being too large by improving the current shift register unit, so as to prevent leakage at Q points and to increase stability of the shift register unit.

### DESCRIPTION OF DRAWINGS

FIG. 1 is a structural schematic diagram of a shift register unit in the prior art.

FIG. 2 is a structural schematic diagram of a shift register unit of an embodiment of the present invention.

FIG. 3 is a schematic diagram of a working timing of the shift register unit shown in FIG. 2.

FIG. 4 is a structural schematic diagram of a gate driving circuit of an embodiment of the present invention.

### DETAILED DESCRIPTION OF PREFERRED EMBODIMENTS

Examples are described below with reference to the appended drawings, and the drawings illustrate particular embodiments in which the present invention may be practiced. Directional terms mentioned in the present invention, such as upper, lower, front, rear, left, right, in, out, side, etc., only refer to directions in the accompanying drawings. Thus, the adoption of directional terms is used to describe and understand the present invention, but not to limit the present invention. In the drawings, units of similar structures are using the same numeral to represent.

In the specification, the claims, and the accompanying drawings, the terms “first”, “second”, and so on are intended to distinguish between similar objects, rather than indicate a specific order or a time order. Moreover, the terms “include”, “have” and any variant thereof mean to cover the non-exclusive inclusion.

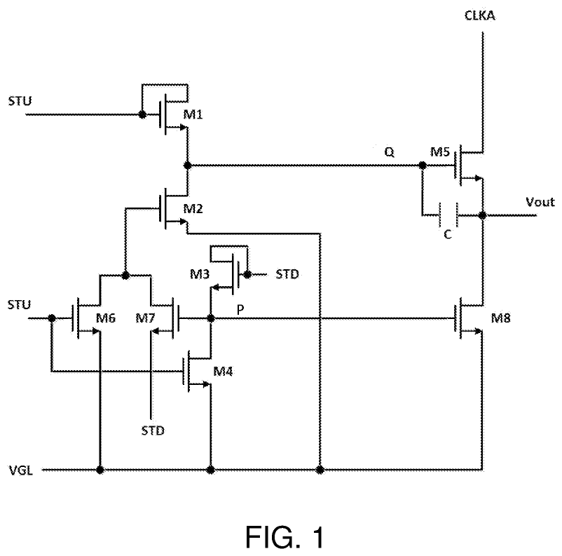

As shown in FIG. 1, a current shift register unit includes a first transistor M1 through an eighth transistor M8, and a bootstrap capacitor C.

A gate and a source of the first transistor M1 both are connected to an output end of an (n−1)th-stage scanning signal, and a drain of the first transistor M1 is connected to a first node Q. The output end of the (n−1)th-stage scanning signal is configured to output the (n−1)th-stage scanning signal, which is indicated by STU herein.

A gate of the fifth transistor M5 is connected to the first node Q, a source of the fifth transistor M5 is connected to a first clock signal CLKA, and a drain of the fifth transistor M5 is connected to an output end of a present-stage scanning signal.

A source and a gate of the third transistor M3 both are connected to an output end of an (n+2)th-stage scanning signal, and a drain of the third transistor M3 is connected to a second node P. The output end of the (n+2)th-stage scanning signal is configured to output the (n+2)th-stage scanning signal, which is indicated by STD herein.

A source of the seventh transistor M7 is connected to the output end of the (n+2)th-stage scanning signal, a gate of the seventh transistor M7 is connected to the second node P, and a drain of the seventh transistor M7 is connected to a gate of the second transistor M2.

A drain of the second transistor M2 is connected to the first node Q. A source of the second transistor M2 is connected to a first low direct current voltage VGL.

A gate of the fourth transistor M4 and a gate of the sixth transistor M6 both are connected to the output end of the (n−1)th-stage scanning signal, a source of the fourth transistor M4 and a source of the sixth transistor M6 both are connected to the first low direct current voltage VGL, and a drain of the fourth transistor M4 is connected to the second node P.

A drain of the sixth transistor M6 is connected to the drain of the seventh transistor M7.

A source of the eighth transistor M8 is connected to the first low direct current voltage VGL, a gate of the eighth transistor M8 is connected to the second node P, and a drain of the eighth transistor M8 is connected to the output end of the present-stage scanning signal. The output end of the present-stage scanning signal is configured to output the present-stage scanning signal Vout.

One end of the bootstrap capacitor C is connected to the first node Q, and another end thereof is connected to the output end of the present-stage scanning signal.

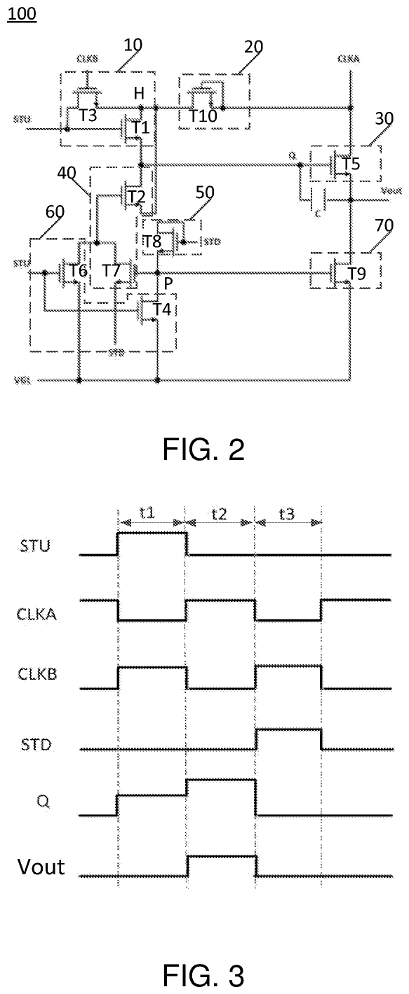

Please refer to FIGS. 2 and 3. FIG. 2 is a structural schematic diagram of a shift register unit of an embodiment of the present invention.

As shown in FIG. 2, a shift register unit 100 of this embodiment includes a pull-up control module 10, a leakage-proof module 20, a pull-up module 30, a first pull-down module 40, a pull-down control module 50, a pull-down holding module 60, a second pull-down module 70, and a bootstrap capacitor C.

The pull-up control module 10 is connected to an output end of the (n−1)th-stage scanning signal, a first node Q, and a third node H. The output end of the (n−1)th-stage scanning signal is configured to output the (n−1)th-stage scanning signal, which is indicated by STU herein. An output end of the (n+2)th-stage scanning signal is configured to output the (n+2)th-stage scanning signal, which is indicated by STD herein. The number n is greater than or equal to 2.

The leakage-proof module 20 is connected to the first clock signal CLKA and the third node H.

The pull-up module 30 is connected to the first clock signal CLKA, the first node Q, and the output end of the present-stage scanning signal. The output end of the present-stage scanning signal is configured to output the preset-stage scanning signal, which is indicated by Vout herein.

The first pull-down module 40 is connected to the output end of the (n+2)th-stage scanning signal, the first node Q, the second node P, and the third node H.

The pull-down control module 50 is connected to the output end of the (n+2)th-stage scanning signal and the second node P.

The pull-down holding module 60 is connected to the output end of the (n−1)th-stage scanning signal, a first low direct current voltage VGL, the second node P, and the first pull-down module 40.

The second pull-down module 70 is connected to the second node P, the output end of the present-stage scanning signal, and the first low direct current voltage VGL.

One end of the bootstrap capacitor C is connected to the first node Q, and another end thereof is connected to the output end of the present-stage scanning signal.

In an embodiment, the leakage-proof module 20 includes a tenth transistor T10. A gate and a source of the tenth transistor T10 both are connected to the first clock signal CLKA, and a drain of the tenth transistor T10 is connected to the third node H.

The pull-up control module 10 includes a first transistor T1 and a third transistor T3. A gate of the first transistor T1 and a source of the third transistor T3 both are connected to the output end of the (n−1)th-stage scanning signal. A drain of the first transistor T1 is connected to the first node Q.

A gate of the third transistor T3 is connected to a second clock signal CLKB, and a drain of the third transistor T3 is connected to the third node H.

The first pull-down module 40 includes a second transistor T2 and a seventh transistor T7. A source of the seventh transistor T7 is connected to the output end of the (n+2)th-stage scanning signal, a gate of the seventh transistor T7 is connected to the second node P, and a drain of the seventh transistor T7 is connected to a gate of the second transistor T2.

A drain of the second transistor T2 is connected to the first node Q, and a source of the second transistor T2 is connected to the third node H.

The pull-down holding module 60 includes a sixth transistor T6 and a fourth transistor T4. A gate of the sixth transistor T6 and a gate of the fourth transistor T4 both are connected to the output end of the (n−1)th-stage scanning signal, and a source of the sixth transistor T6 and a source of the fourth transistor T4 both are connected to the first low direct current voltage VGL.

A drain of the sixth transistor T6 is connected to the drain of the seventh transistor T7 and the gate of the second transistor T2. A drain of the fourth transistor T4 is connected to the second node P.

The pull-down control module 50 includes an eighth transistor T8. A source and a gate of the eighth transistor T8 both are connected to the output end of the (n+2)th-stage scanning signal, and a drain of the eighth transistor T8 is connected to the second node P.

The second pull-down module 70 includes a ninth transistor T9. A source of the ninth transistor T9 is connected to the first low direct current voltage VGL, a gate of the ninth transistor T9 is connected to the second node P, and a drain of the ninth transistor T9 is connected to the output end of the present-stage scanning signal.

The pull-up module 30 includes a fifth transistor T5. A gate of the fifth transistor T5 is connected to the first node Q, a source of the fifth transistor T5 is connected to the first clock signal CLKA, and a drain of the fifth transistor T5 is connected to the output end of the present-stage scanning signal.

The first transistor T1 through the tenth transistor T10 can be P-type transistors or N-type transistors.

With reference to FIG. 3, taking the first transistor T1 through the tenth transistor T10 as the N-type transistors as an example, a specific working principle of the shift register unit in this embodiment is as follows.

(1) Period t1: STU and CLKB both are at a high level, and STD and CLKA both are at a low level.

T3 and T1 are turned on, Q point is set to the high level, T5 is turned on, CLKA is at the low level, so the output signal Vout is at the low level. T4 and T6 are turned on, T7 is turned off, and T2 is turned off. T8, T9, and T10 are turned off.

(2) Period t2: STU, STD, and CLKB are all at the low level, and CLKA is at the high level.

T3 and T1 are turned off, T10 is turned on, the source of T1 and the source of T2 are respectively pulled to a high electric potential, so Q point can be prevented from occurring a leakage. CLKA is at the high level, and the bootstrap capacitor C further increases a voltage of the Q point, thereby making T5 to be fully turned on, which in turn increases an output current, and the output signal Vout is at the high level.

Because STU and STD are at the low level, T7, T8, T9, T4, and T6 are all turned off.

(3) Period t3: STU and CLKA are at the low level, and STD and CLKB are at high level.

Because CLKB is at the high level, T3 is turned on. Because STU is at a low electric potential, an electric potential of the source of T2 is pulled low.

Because STD is at the high electric potential, T8, T7, T2 are turned on, and an electric potential of the Q point is pulled low to complete a reset.

In addition, T8 is turned on, so T9 is turned on, a level of the output signal Vout is pulled low by VGL to complete the reset, and the remaining T4, T5, T6, and T10 are all turned off. It can be understood that when the first transistor T1 through the tenth transistor T10 can be P-type transistors, and their working principle is similar to this.

When the Q point is at the high electric potential, the source of T1 and the source of T2 are respectively pulled to the high electric potential through the leakage-proof module, preventing formation of large voltage differences between the sources and the drains of the transistors in the pull-up control module and the pull-down module and thus causing leakage at Q point, thereby increasing stability of the shift register unit. In additional, compared to FIG. 1, because the present invention does not require a direct current high potential signal, it simplifies a circuit structure and reduces production costs.

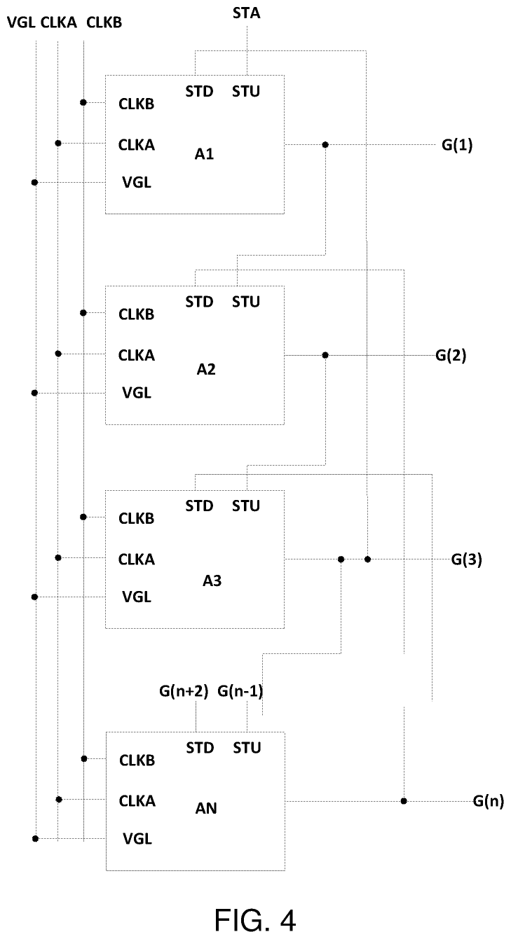

As shown in FIG. 4, the present invention further provides a gate driving circuit including a plurality of any one of the cascaded shift register units 100 above, that is, any one of A1 through AN can use the above shift register unit. Signals are respectively output from the output end of the present-stage scanning signal of A1 through AN are G(1) through G(n), wherein n is greater than or equal to 2.

A reset signal STD of an nth-stage shift register unit of the present invention uses an output signal of an (n+2)th-stage shift register unit, so it does not need to additionally connect a reset signal, which simplifies a circuit structure and reduces production costs.

STU of a third-stage shift register unit A3 is an output signal of a second-stage shift register unit A2. Because a STU signal of the first-stage shift register unit A1 is connected to a start signal STA, STA can be an output signal of a dummy unit of a previous-stage.

STD of the first-stage shift register unit A1 is an output signal of the third-stage shift register unit A3. A STD signal of a last-stage shift register unit AN uses an output signal of a dummy unit of a next-stage as a STD signal of a last-stage shift register unit AN.

The present invention further provides a display panel including the above gate driving circuit.

The shift register unit, the gate drive circuit, and the display panel of the present invention can prevent the formation of large voltage differences between the sources and the drains of the transistors in the pull-up control module and the pull-down module by improving the current shift register unit, so as to prevent leakage at Q points and to increase stability of the shift register unit.

Although the present invention has been disclosed above with the preferred embodiments, it is not intended to limit the present invention. Persons having ordinary skill in this technical field can still make various alterations and modifications without departing from the scope and spirit of this invention. Therefore, the scope of the present invention should be defined and protected by the following claims and their equivalents.

What is claimed is:

1. A shift register unit, comprising:
a pull-up control module connected to an output end of an (n−1)th-stage scanning signal, a first node, and a third node, wherein n is greater than or equal to 2;
a pull-up module connected to a first clock signal, the first node, and an output end of a present-stage scanning signal;
a leakage-proof module connected to the first clock signal and the third node;
a pull-down control module connected to an output end of an (n+2)th-stage scanning signal and a second node;
a first pull-down module connected to the output end of the (n+2)th-stage scanning signal, the first node, the second node, and the third node;
a pull-down holding module connected to the output end of the (n−1)th-stage scanning signal, a first low direct current voltage, the second node, and the first pull-down module;
a second pull-down module connected to the second node, the output end of the present-stage scanning signal, and the first low direct current voltage; and
a bootstrap capacitor, wherein one end of the bootstrap capacitor is connected to the first node, and another end of the bootstrap capacitor is connected to the output end of the present-stage scanning signal.

2. The shift register unit according to claim 1, wherein the leakage-proof module comprises a tenth transistor; and
a gate and a source of the tenth transistor both are connected to the first clock signal, and a drain of the tenth transistor is connected to the third node.

3. The shift register unit according to claim 1, wherein the pull-up control module comprises a first transistor and a third transistor;
a gate of the first transistor and a source of the third transistor both are connected to the output end of the (n−1)th-stage scanning signal;
a drain of the first transistor is connected to the first node; and
a gate of the third transistor is connected to a second clock signal, and a drain of the third transistor is connected to the third node.

4. The shift register unit according to claim 1, wherein the first pull-down module comprises a second transistor and a seventh transistor;
a source of the seventh transistor is connected to the output end of the (n+2)th-stage scanning signal, a gate of the seventh transistor is connected to the second node, and a drain of the seventh transistor is connected to a gate of the second transistor; and
a drain of the second transistor is connected to the first node, and a source of the second transistor is connected to the third node.

5. The shift register unit according to claim 4, wherein the pull-down holding module comprises a sixth transistor and a fourth transistor;
a gate of the sixth transistor and a gate of the fourth transistor both are connected to the output end of the (n−1)th-stage scanning signal, and a source of the sixth transistor and a source of the fourth transistor both are connected to the first low direct current voltage;
a drain of the sixth transistor is connected to the drain of the seventh transistor and the gate of the second transistor; and
a drain of the fourth transistor is connected to the second node.

6. The shift register unit according to claim 1, wherein the pull-down control module comprises an eighth transistor; and
a source and a gate of the eighth transistor both are connected to the output end of the (n+2)th-stage scanning signal, and a drain of the eighth transistor is connected to the second node.

7. The shift register unit according to claim 1, wherein the second pull-down module comprises a ninth transistor; and
a source of the ninth transistor is connected to the first low direct current voltage, a gate of the ninth transistor is connected to the second node, and a drain of the ninth transistor is connected to the output end of the present-stage scanning signal.

8. The shift register unit according to claim 1, wherein the pull-up module comprises a fifth transistor; and
a gate of the fifth transistor is connected to the first node, a source of the fifth transistor is connected to the first clock signal, and a drain of the fifth transistor is connected to the output end of the present-stage scanning signal.

9. A gate driving circuit, comprising a shift register unit, wherein the shift register unit comprises:
a pull-up control module connected to an output end of an (n−1)th-stage scanning signal, a first node, and a third node, wherein n is greater than or equal to 2;
a pull-up module connected to a first clock signal, the first node, and an output end of a present-stage scanning signal;
a leakage-proof module connected to the first clock signal and the third node;
a pull-down control module connected to an output end of an (n+2)th-stage scanning signal and a second node;
a first pull-down module connected to the output end of the (n+2)th-stage scanning signal, the first node, the second node, and the third node;
a pull-down holding module connected to the output end of the (n−1)th-stage scanning signal, a first low direct current voltage, the second node, and the first pull-down module;
a second pull-down module connected to the second node, the output end of the present-stage scanning signal, and the first low direct current voltage; and
a bootstrap capacitor, wherein one end of the bootstrap capacitor is connected to the first node, and another end of the bootstrap capacitor is connected to the output end of the present-stage scanning signal.

10. The gate driving circuit according to claim 9, wherein the leakage-proof module comprises a tenth transistor; and
a gate and a source of the tenth transistor both are connected to the first clock signal, and a drain of the tenth transistor is connected to the third node.

11. The gate driving circuit according to claim 9, wherein the pull-up control module comprises a first transistor and a third transistor;
a gate of the first transistor and a source of the third transistor both are connected to the output end of the (n−1)th-stage scanning signal;
a drain of the first transistor is connected to the first node; and
a gate of the third transistor is connected to a second clock signal, and a drain of the third transistor is connected to the third node.

12. The gate driving circuit according to claim 9, wherein the first pull-down module comprises a second transistor and a seventh transistor;
a source of the seventh transistor is connected to the output end of the (n+2)th-stage scanning signal, a gate of the seventh transistor is connected to the second node, and a drain of the seventh transistor is connected to a gate of the second transistor; and
a drain of the second transistor is connected to the first node, and a source of the second transistor is connected to the third node.

13. The gate driving circuit according to claim 12, wherein the pull-down holding module comprises a sixth transistor and a fourth transistor;
a gate of the sixth transistor and a gate of the fourth transistor both are connected to the output end of the (n−1)th-stage scanning signal, and a source of the sixth transistor and a source of the fourth transistor both are connected to the first low direct current voltage;
a drain of the sixth transistor is connected to the drain of the seventh transistor and the gate of the second transistor; and
a drain of the fourth transistor is connected to the second node.

14. The gate driving circuit according to claim 9, wherein the pull-down control module comprises an eighth transistor; and
a source and a gate of the eighth transistor both are connected to the output end of the (n+2)th-stage scanning signal, and a drain of the eighth transistor is connected to the second node.

15. The gate driving circuit according to claim 9, wherein the second pull-down module comprises a ninth transistor; and
a source of the ninth transistor is connected to the first low direct current voltage, a gate of the ninth transistor is connected to the second node, and a drain of the ninth transistor is connected to the output end of the present-stage scanning signal.

16. The gate driving circuit according to claim 9, wherein the pull-up module comprises a fifth transistor; and
a gate of the fifth transistor is connected to the first node, a source of the fifth transistor is connected to the first clock signal, and a drain of the fifth transistor is connected to the output end of the present-stage scanning signal.

17. A display panel, comprising a gate driving circuit, wherein the gate driving circuit comprises a shift register unit, and the shift register unit comprises:
a pull-up control module connected to an output end of an (n−1)th-stage scanning signal, a first node, and a third node, wherein n is greater than or equal to 2;
a pull-up module connected to a first clock signal, the first node, and an output end of a present-stage scanning signal;
a leakage-proof module connected to the first clock signal and the third node;
a pull-down control module connected to an output end of an (n+2)th-stage scanning signal and a second node;
a first pull-down module connected to the output end of the (n+2)th-stage scanning signal, the first node, the second node, and the third node;
a pull-down holding module connected to the output end of the (n−1)th-stage scanning signal, a first low direct current voltage, the second node, and the first pull-down module;
a second pull-down module connected to the second node, the output end of the present-stage scanning signal, and the first low direct current voltage; and
a bootstrap capacitor, wherein one end of the bootstrap capacitor is connected to the first node, and another end of the bootstrap capacitor is connected to the output end of the present-stage scanning signal.

18. The display panel according to claim 17, wherein the leakage-proof module comprises a tenth transistor; and
a gate and a source of the tenth transistor both are connected to the first clock signal, and a drain of the tenth transistor is connected to the third node.

19. The display panel according to claim 17, wherein the pull-up control module comprises a first transistor and a third transistor;
a gate of the first transistor and a source of the third transistor both are connected to the output end of the (n−1)th-stage scanning signal;
a drain of the first transistor is connected to the first node; and
a gate of the third transistor is connected to a second clock signal, and a drain of the third transistor is connected to the third node.

20. The display panel according to claim 17, wherein the first pull-down module comprises a second transistor and a seventh transistor;
a source of the seventh transistor is connected to the output end of the (n+2)th-stage scanning signal, a gate of the seventh transistor is connected to the second node, and a drain of the seventh transistor is connected to a gate of the second transistor; and
a drain of the second transistor is connected to the first node, and a source of the second transistor is connected to the third node.
